(19) United States
(12) Patent Application Publication
(10) Pub. No.: US 2017/0163390 A1
(43) Pub. Date: Jun. 8, 2017

(54) SYSTEM AND METHOD FOR USING OFDM REDUNDANCY FOR OPTIMAL COMMUNICATION

(71) Applicant: TEJAS NETWORKS LIMITED, Bangalore (IN)

(72) Inventor: VINOD KUMAR MADAIAH, Bangalore (IN)

(21) Appl. No.: 15/341,082

(22) Filed: Nov. 2, 2016

(30) Foreign Application Priority Data
Nov. 2, 2015 (IN) 5934/CHE/2015

(51) Int. Cl. H04L 1/22; H03M 13/03; H04B 1/74; G06F 11/16; H04B 17/309; H04L 27/26

(52) U.S. Cl. CPC H04L 1/22; H04B 17/309; H04L 27/2695; H04B 1/74; G06F 11/16; H03M 13/03

(57) ABSTRACT

Embodiments of the disclosure relates to systems and methods for determining redundancy in OFDM, using the redundancy to trade off redundancy in any or a combination (n,k) block codes, OFDM codeword, and PAPR of OFDM with each other and also with that of transmission power, frequency and time, so as to provide optimal transmission/reception and spectral efficiency.

### RELATED APPLICATIONS

Benefit is claimed under 35 U.S.C. 119(a)-(d) to Foreign application Serial No. 5934/CHE/2015 filed in India entitled “SYSTEM AND METHOD FOR USING OFDM REDUNDANCY FOR OPTIMAL COMMUNICATION”, on Nov. 2, 2015, by TEJAS NETWORKS LIMITED, which is herein incorporated in its entirety by reference for all purposes.

### TECHNICAL FIELD

The present disclosure relates to the field of orthogonal frequency division multiplexing (OFDM) coded transmission. More particularly, the present disclosure relates to a system and method for using redundancy available in OFDM scheme for optimal communication and spectral efficiency.

### BACKGROUND

Background description includes information that may be useful in understanding the present invention. It is not an admission that any of the information provided herein is prior art or relevant to the presently claimed invention, or that any publication specifically or implicitly referenced is prior art.

Transmission and storage of digital information have much in common. Both processes transfer data from an information source to a destination. FIG. 1 illustrates exemplary functional blocks of a communication system. Similar blocks may be used for storage system. On transmitter side, information source 102, which can be either a person or a machine, for example, a digital computer, or a data terminal, can generate message or data that needs to be sent across a network to a destination 120, wherein the destination 120, also referred interchangeably as receiver, can be configured to receive either a continuous waveform or a sequence of discrete symbols. On transmitter, a source encoder 104 transforms a source output, which can be a message or data generated by the source 102, into a sequence of binary digits (bits) called the information sequence. In case the source 102 is producing a continuous signal, an analog-to-digital (A/D) converter can be placed before the source encoder 104. The source encoder 104 is ideally designed so that (1) the number of bits per unit time required to represent the source output is minimized, and (2) the source output can be unambiguously reconstructed from the received information sequence.

On transmitter side, a channel encoder 106 can be provided to transform the information sequence into a discrete encoded sequence called a codeword. In most instances, encoded sequence is also a binary sequence, although in some applications non-binary codes have been used. The channel encoder 106 needs to be designed in an efficient manner so as to combat the possible noisy environment in which the codewords are generally transmitted.

As we know, discrete symbols are not suitable for transmission over a physical channel or recording on a digital storage medium. A modulator 108 can be used to transform each output symbol of the channel encoder 106 into a waveform of duration T seconds that is suitable for transmission. This waveform enters the channel 110 that may have some noise 112. Typical transmission channels 112 include telephone lines, mobile cellular telephony, high-frequency radio, telemetry, microwave and satellite links, optical fiber cables, and so on. Each of these example channels is subject to various types of noise disturbances. On a telephone line and a mobile cellular telephony, the disturbance may come from switching impulse noise, thermal noise, or crosstalk from other lines. Radio elements (e.g. Mobile Phone and Base Station) of mobile cellular telephony will additionally have other disturbances such as Rayleigh fading and Doppler shift.

Orthogonal frequency-division multiplexing (OFDM) is one of the best methods for transmitting digital data on multiple carrier frequencies. A large number of closely spaced orthogonal sub-carrier signals are used to carry data on several parallel data streams or channels. Each sub-carrier can be modulated with a conventional modulation scheme (such as quadrature amplitude modulation or phase-shift keying) at a low symbol rate, maintaining total data rates similar to conventional single-carrier modulation schemes in the same bandwidth. The OFDM scheme can be used in various applications such as digital television and audio broadcasting, DSL Internet access, wireless networks, power-line networks, and 4G mobile communications. OFDM provides promising approach for transmitting digital symbols through a dispersive channel. It has already been adopted for Digital Video Broadcast (DVB) in Europe, WLAN standards like IEEE 802.11a and 802.11g, 4G and 5G digital cellular communication. The primary advantage of OFDM over single-carrier schemes is its ability to cope with severe channel conditions (for example, attenuation of high frequencies in a long copper wire, narrowband interference and frequency-selective fading due to multipath) without complex equalization filters.

On receiver side, a demodulator 114 processes each received waveform of duration T, and produces either a discrete (quantized) or a continuous (unquantized) output. The sequence of demodulator outputs corresponding to the encoded sequence is referred as received sequence.

A channel decoder 116 can transform the received sequence into a binary sequence called the estimated information sequence. The decoding strategy is based on the rules of channel encoding and the noise characteristics of the channel (or storage medium). Ideally, the estimated information sequence will be a replica of the information sequence, although noise may cause some decoding errors.

A source decoder 118 transforms the estimated information sequence into an estimate of the source output and delivers to the destination 120. In a well-designed communication system, the estimated information sequence can be a faithful reproduction of the source output except when the channel (or storage medium) is very noisy. Different types of codes, such as block code, convolution code, etc., are used by the encoders.

It an object of any communication mechanism to minimize the number of bits per unit time required to create information sequence, which is binary representation of source data that can be transmitted by a transmitter so that a receiver can reconstruct the source data by performing error correction. Redundancies are introduced in communication systems so as to improve error correction capabilities of the communication system at receiver side. As one may appreciate the error correction capability of any communication system is directly proposal to the redundancy introduced by the transmitter.

On transmitter side, redundant bits are added at different stage to each message to form a codeword, which can be received at the receiver side and reconstructed by the receiver, even if some error due to channel noise has been introduced in the codeword. These redundant bits provide the code with the capability of combating the channel noise or disturbances.

For example, an encoder using block code divides the information sequence into message blocks of k information bits (symbols) each. A message block is represented by the binary k-tuple u=(u₀, u₁, . . . , uₖ₋₁), called a message. (In block coding, the symbol u is used to denote a k-bit message rather than the entire information sequence). There are a total of 2^{k} different possible messages. The encoder transforms each message u independently into an n-tuple C=(c₀, c₁, . . . , cₙ₋₁) of discrete symbols, called a codeword. (In block coding, the symbol C is used to denote an n-symbol block rather than the entire encoded sequence.) Therefore, corresponding to the 2^{k} different possible messages, there are 2^{k} different possible codewords at the encoder output. This set of 2^{k} codewords of length n is called an (n,k) block code. A ratio R=k/n called the code rate can be interpreted as the number of information bits entering the encoder per transmitted symbol. Because the n-symbol output codeword depends only on the corresponding k-bit input message, it is apparent that each message is encoded independently.

In a binary code, each codeword C is also binary. Hence, for a binary code to be useful, that is, to have a different codeword assigned to each message, k≦n, or R≦1. When k<n, n−k redundant bits are added to each message to form a codeword. These redundant bits provide the code with the capability of combating the channel noise or disturbances.

As we know, error correction capability of a receiver for the redundancy dₘᵢₙ=n−k, is

$${t}_{H} = \frac{{d}_{min} - 1}{2} .$$

The error correction capability is the capability of the receiver to correct number of error present in a codeword at the receiver side, of the communication system. However with increased redundancy, efficiency of the communication system suffers heavily and infrastructural requirements increases exponentially. The redundancy present in the communication system reduces the spectrum efficiency.

Therefore, there is required a system and method that can reduce redundancy in transmitted codeword without compromising error correction capabilities of the communication system. Systems and methods are required to change codeword size of ODFM codeword dynamically based on channel condition. Systems and methods are also required for ODFM coded transmission that provides optimal spectral efficiency usage by reducing the redundancy in the communication system.

In some embodiments, numerical parameters set forth in the written description are approximations that can vary depending upon the desired properties sought to be obtained by a particular embodiment. In some embodiments, the numerical parameters should be construed in light of the number of reported significant digits and by applying ordinary rounding techniques. Notwithstanding that, the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Marcus groups used in the appended claims.

### OBJECTS OF THE INVENTION

An object of the present disclosure is to provide systems and methods for ODFM coded transmission with optimal redundancy in the transmitted codeword.

An object of the present disclosure is to provide systems and methods of ODFM coded transmission with optimal redundancy in the transmitted codeword, without compromising the error correction capabilities of the communication system.

Another object of the present disclosure is to provide systems and methods that can change codeword size of ODFM codeword dynamically based on channel condition.

An object of the present disclosure is to provide systems and methods that can determine the required redundancy in communication and trade-off redundancies created at different stages of transmission.

An object of the present disclosure is to provide systems and methods for OFDM coded transmission and reception without requiring addition of any cyclic prefix.

An object of the present disclosure is to provide systems and methods for OFDM coded transmission that can enable or disable usage of cyclic prefix.

An object of the present disclosure is to provide systems and methods for OFDM coded transmission for improving communication efficiency by reducing N, preferably making, N=k for a (N,K) block code, without reducing the error correction capability of the communication system.

An object of the present disclosure is to provide systems and methods for OFDM coded transmission with improved spectral efficiency.

### SUMMARY

Embodiments of the present disclosure relate to systems and methods for ODFM coded transmission with reduced redundancy in the transmitted codeword. It has been observed and identified that the OFDM scheme has inherent redundancy built in it. The systems and methods for OFDM transmission and reception are proposed that use available redundancy of the OFDM scheme.

An embodiment of the present disclosure provides an OFDM coded transmission system that can use inherent redundancy of OFDM. The system can be configured to trade off redundancy of OFDM scheme with redundancy of (n,k) block codes, PAPR of OFDM with each other, and also with that of redundancy of transmission power, frequency and time, so as to provide optimal transmission/reception efficiency. The ODFM coded transmission system can be configured to reduce redundancy in the transmitted codeword without compromising the error correction capabilities of receiver of the communication system by reducing symbols size of OFDM codeword. The ODFM coded transmission system can be configured to determine redundancy requirement based on channel quality and trade-off inherent redundancy of OFDM scheme to reduced/eliminate redundancy introduced by the (n,k) block, cyclic prefix and other such redundancies in the coded transmission.

Embodiments of the present disclosure relate to systems and methods for identifying redundancy in OFDM scheme and using the available redundancies in OFDM scheme for transmission optimization. In an embodiment, systems and methods of present disclosure can be configured to discover and quantify redundancy in OFDM codeword and trade off the OFDM redundancy with redundancy in (n,k) codeword, network resources (power, frequency, time) and network efficiency.

An embodiment of the present disclosure provides OFDM coded transmission system that can include a channel quality estimation module that can be configured to determine channel quality between a transmitter and a receiver; an OFDM codeword size and duration control module 204 that can be configured to control OFDM codeword size and duration based on the channel quality; an OFDM redundancy based error correction module that can be configured to use ODFM redundancy for error correction; and an OFDM redundancy trade-off module that can be configured to trade off OFDM redundancy with redundancy in (n,k) codeword, network resources (power, frequency, time), PAPR minimizer/reversal, addition/removal of Cyclic Prefix, removal of symbols from OFDM codeword and OFDM codeword decoder.

In an exemplary embodiment, channel quality estimation module can be configured to use any known method for estimating channel quality between a transmitter and receiver. For instance, channel quality estimation module can be configured to use a beacon based quality estimation method.

Based on the estimated channel quality, system of the present disclosure can determine the amount of redundancy required for optimal communication between the transmitter and receiver. In an exemplary implementation, if the channel quality is good, the message transmission and reception can be performed with less redundancy in the system. Based on the estimated channel quality, the system can be configured to trade-off redundancy of OFDM scheme with other redundancies available in the system. In an exemplary implementation, OFDM codeword size and duration control module can be configured to control OFDM codeword size and duration based on the estimated channel quality. For example, if the channel quality is good, the system can enable communication with reduced symbols size and duration.

In an exemplary embodiment, the OFDM codeword size and duration control module can be configured to control the number of OFDM symbols to be used for transmitting the OFDM codeword such that OFDM codeword decoder can successfully decode the OFDM codeword without any risk. In an exemplary embodiment, the OFDM codeword size and duration control module can be configured to reduce duration of OFDM codeword. Removal of symbols from OFDM codeword results in shortened codeword of duration lesser than the duration of the original OFDM codeword or codeword with lesser symbols but of same duration as the original OFDM codeword before removal of symbol.

In an exemplary embodiment, the OFDM redundancy based error correction module can be configured to correct error present in the received OFDM sequence using the OFDM redundancy in OFDM scheme that have inherent redundancy, for example due to IFFT matrix and FFT matrix.

The OFDM redundancy trade-off module can be configured to enable trade-off between ODFM redundancy and other redundancies available in the system. The ODFM redundancy trade-off module can be configured to trade-off redundancy due to one or more of cyclic prefix, OFDM codeword size and duration, PAPR, (K,N) block code etc. The OFDM redundancy trade-off module can include exemplary modules such as a PAPR trade-off module that can be configured to trade-off/minimize redundancy due to PAPR minimiser, a (N,K) block code trade-off module that can be configured to reduce N, preferably make N=K, and a cyclic prefix trade-off module that can be configured to control size of cyclic prefix.

The cyclic prefix trade-off module can be configured to control size of cyclic prefix, example by reducing/increasing size of cyclic prefix, or enabling or disabling cyclic prefix.

One or more module of the system can be implemented by a redundancy controller that can be configured to control redundancy due to (n,k) encoder/decoder, PAPR minimizer/reversal, addition/removal of Cyclic Prefix, removal of symbols from OFDM codeword and OFDM codeword decoder.

In an exemplary embodiment, the system can include a OFDM controller that can be configured to control redundancy due to (n,k) encoder/decoder, PAPR minimizer/reversal, addition/removal of Cyclic Prefix, removal of symbols from OFDM codeword and OFDM codeword decoder. The redundancy controller can be configured to control the number of OFDM symbols to be used for transmitting the OFDM codeword such that OFDM codeword decoder can successfully decode the OFDM codeword without any risk. Removal of symbols from OFDM codeword results in shortened codeword of duration lesser than the duration of the original OFDM codeword or codeword with lesser symbols but of same duration as the original OFDM codeword before removal of symbol. Various actions taken by the redundancy controller at the transmitter can be negotiated with the redundancy controller at the receiver before transmission of any message.

The redundancy controller can be configured to control redundancy due to (n,k) encoder/decoder, PAPR minimizer/reversal, addition/removal of Cyclic Prefix, removal of symbols from OFDM codeword and OFDM codeword decoder.

In an exemplary embodiment, transmitter of the OFDM coded transmission system can be configured to include a PAPR minimizes that can process encoded symbols to minimize the PAPR of the OFDM codeword transmitted over the channel, and a cyclic prefix block that can be enabled or disabled by trading off with OFDM redundancy. In an exemplary embodiment, if high redundancy is not required from (n,k) Encoder/Decoder, Redundancy Controller can make n=k.

### BRIEF DESCRIPTION OF THE DRAWINGS

In the Figures, similar components and/or features may have the same reference label. Further, various components of the same type may be distinguished by following the reference label with a second label that distinguishes among the similar components. If only the first reference label is used in the specification, the description is applicable to any one of the similar components having the same first reference label irrespective of the second reference label.

FIG. 1 illustrates exemplary functional blocks of a communication system.

FIG. 2 illustrates exemplary functional blocks of a transmitter configured to perform OFDM coded transmission in accordance with an embodiment of the present disclosure.

FIG. 3A illustrates an exemplary functional blocks of a receiver configured to receive OFDM codeword and generate corrected information sequence in accordance with an embodiment of the present disclosure.

FIG. 3B illustrates a high level architecture of the OFTM coded transmission employing a redundancy controller in accordance with an embodiment of the present disclosure.

FIG. 4 illustrates exemplary functional modules of the OFDM coded transmission-reception system in accordance with an embodiment of the present disclosure.

FIG. 5 illustrates an exemplary case of reduced symbol size for the OFDM coded transmission achieved in accordance with an embodiment of the present disclosure.

FIG. 6 illustrates an exemplary flow diagram showing use of OFDM redundancy in accordance with an embodiment of the present disclosure.

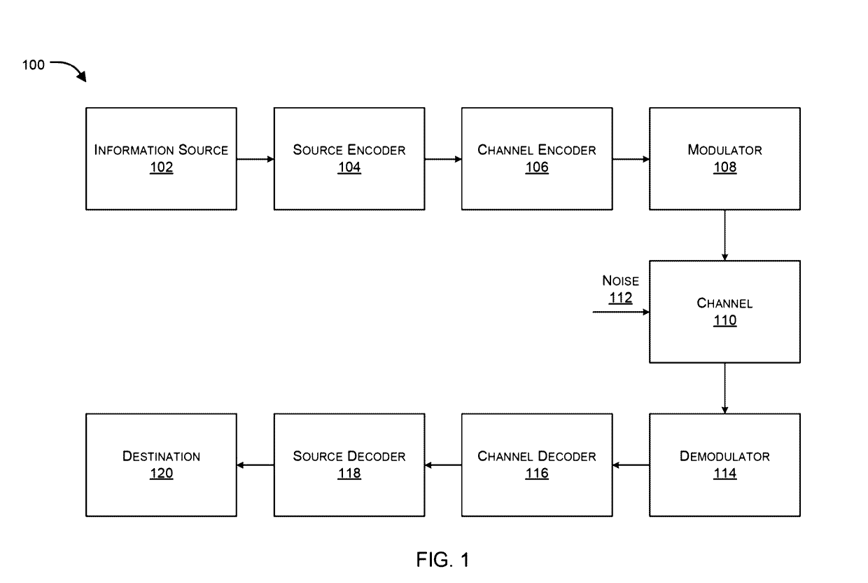

### DETAILED DESCRIPTION

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims.

Each of the appended claims defines a separate invention, which for infringement purposes is recognized as including equivalents to the various elements or limitations specified in the claims. Depending on the context, all references below to the “invention” may in some cases refer to certain specific embodiments only. In other cases it will be recognized that references to the “invention” will refer to subject matter recited in one or more, but not necessarily all, of the claims.

Various terms as used herein are shown below. To the extent a term used in a claim is not defined below, it should be given the broadest definition persons in the pertinent art have given that term as reflected in printed publications and issued patents at the time of filing.

Embodiments of the present disclosure relate to systems and methods for ODFM coded transmission with reduced redundancy in the transmitted codeword. It has been observed and identified that the OFDM scheme has inherent redundancy built in it. The systems and methods for OFDM transmission and reception are proposed that use available redundancy of the OFDM scheme.

An embodiment of the present disclosure provides an OFDM coded transmission system that can use inherent redundancy of OFDM. The system can be configured to trade off redundancy of OFDM scheme with redundancy of (n,k) block codes, PAPR of OFDM with each other and also with that of redundancy of transmission power, frequency and time, so as to provide optimal transmission/reception. The ODFM coded transmission system can be configured to reduce redundancy in the transmitted codeword without compromising the error correction capabilities of receiver of the communication system by reducing symbols size of codeword. The ODFM coded transmission system can be configured to determine redundancy requirement based on channel quality and trade-off inherent redundancy of OFDM scheme to reduce/eliminate redundancy introduced by the (n,k) block code, cyclic prefix and other such redundancies in the coded transmission.

Embodiments of the present disclosure relate to systems and methods for identifying redundancy in OFDM scheme and using the available redundancies in OFDM scheme for transmission optimization. In an embodiment, systems and methods of the present disclosure can be configured to discover and quantify redundancy in OFDM codeword and trade off the OFDM redundancy with redundancy in (n,k) codeword, network resources (power, frequency, time) and network efficiency.

An embodiment of the present disclosure provides OFDM coded transmission system that can include a channel quality estimation module that can be configured to determine the channel quality between a transmitter and a receiver, an OFDM codeword size and duration control module that can be configured to control OFDM codeword size and duration based on the channel quality, an OFDM redundancy based error correction module that can be configured to use ODFM redundancy for error correction, and an OFDM redundancy trade-off module that can be configured to trade off OFDM redundancy with redundancy in (n/k) codeword, network resources (power, frequency, time) and network efficiency, by controlling redundancy due to one or a combination of (n,k) encoder/decoder, PAPR minimizer/reversal, addition/removal of Cyclic Prefix, removal of symbols from OFDM codeword, and OFDM codeword decoder.

In an exemplary embodiment, the OFDM codeword size and duration control module can be configured to control the number of OFDM symbols to be used for transmitting the OFDM codeword such that OFDM codeword decoder can successfully decode the OFDM codeword without any risk. In an exemplary embodiment, the OFDM codeword size and duration control module can be configured to reduce duration of OFDM codeword. Removal of symbols from OFDM codeword results in shortened codeword of duration lesser than the duration of the original OFDM codeword or codeword with lesser symbols but of same duration as the original OFDM codeword before removal of symbol.

The redundancy controller can be configured to control redundancy due to (n,k) encoder/decoder, PAPR minimizer/reversal, addition/removal of Cyclic Prefix, removal of symbols from OFDM codeword and OFDM codeword decoder.

In an exemplary embodiment, the system can include a OFDM controller that can be configured to control redundancy due to (n,k) encoder/decoder, PAPR minimizer/reversal, addition/removal of Cyclic Prefix, removal of symbols from OFDM codeword and OFDM codeword decoder. The redundancy controller can be configured to control the number of OFDM symbols to be used to transmit the OFDM codeword such that OFDM codeword decoder can successfully decode the OFDM codeword without any risk. Removal of symbols from OFDM codeword results in shortened codeword of duration lesser than the duration of the original OFDM codeword or codeword with lesser symbols but of same duration as the original OFDM codeword before removal of symbol. Various actions taken by the redundancy controller at the transmitter can be negotiated with the redundancy controller at the receiver before transmission of any message.

The redundancy controller can be configured to control redundancy due to (n,k) encoder/decoder, PAPR minimizer/reversal, addition/removal of Cyclic Prefix, removal of symbols from OFDM codeword and OFDM codeword decoder.

In an exemplary embodiment, transmitter of the OFDM coded transmission system can be configured to include a PAPR minimizer that can process encoded symbols to minimize the PAPR of the OFDM codeword transmitted over the channel, and a cyclic prefix block that can be enabled or disabled by trade off with OFDM redundancy. In an exemplary embodiment, if high redundancy is not required from (n,k) Encoder/Decoder, Redundancy Controller can make n=k.

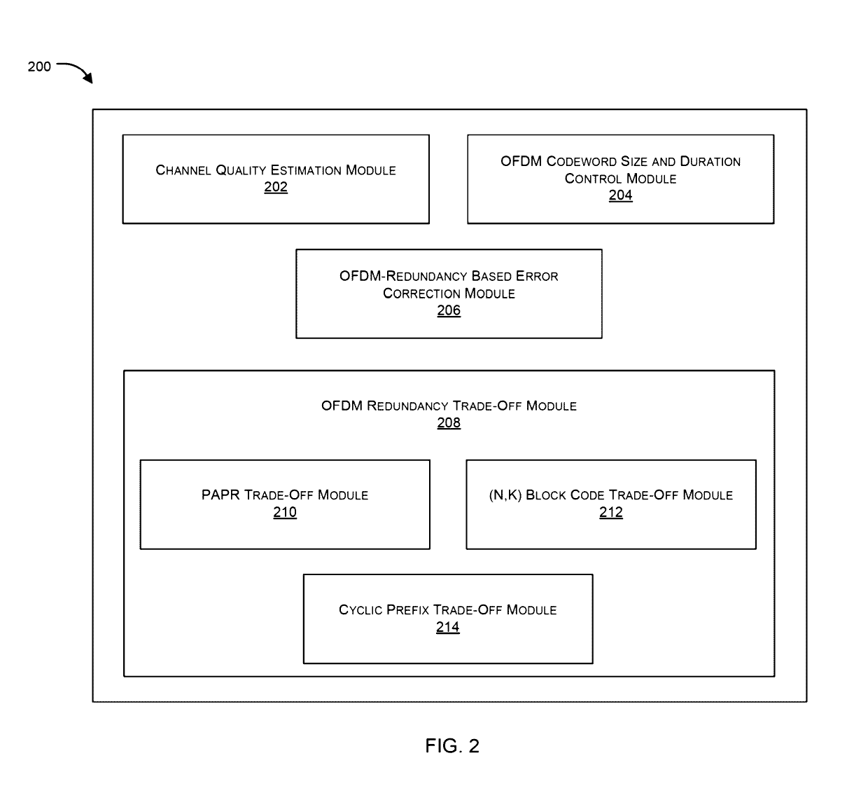

FIG. 2 illustrates exemplary functional modules of the OFDM coded transmission-reception system in accordance with an embodiment of the present disclosure. An embodiment of the present disclosure provides an OFDM coded transmission system 200 that can include a channel quality estimation module 202 that can be configured to determine the channel qualify between a transmitter and a receiver, an OFDM codeword size and duration control module 204 that can be configured to control OFDM codeword size and duration based on the channel quality, an OFDM redundancy based error correction module 206 that can be configured to use ODFM redundancy for error correction, and an OFDM redundancy trade-off module that can be configured to trade off OFDM redundancy with redundancy in (n,k) codeword, network resources (power, frequency, time), PAPR minimizer/reversal, addition/removal of Cyclic Prefix, removal of symbols from OFDM codeword and OFDM codeword decoder.

In an exemplary embodiment, channel quality estimation module 202 can be configured to use any known method for estimating the channel quality between a transmitter and receiver. For example, channel quality estimation module 202 can be configured to use a beacon based quality estimation method.

Based on the estimated channel quality, the system 200 can determine the amount of redundancy required for optimal communication between the transmitter and receiver. In an exemplary implementation, if the channel quality is good, the message transmission and reception can be performed with less redundancy in the system. Based on the estimated channel quality, the system 200 can be configured to tradeoff redundancy of OFDM scheme with other redundancies available in the system. In an exemplary implementation, the OFDM codeword size and duration control module 204 can be configured to control OFDM codeword size and duration based on the estimated channel quality. For example, if the channel quality is good, the system 200 can enable communication with reduced codeword size and duration.

In an exemplary embodiment, the OFDM codeword size and duration control module 204 can be configured to control the number of OFDM symbols to be used for transmitting the OFDM codeword such that OFDM codeword decoder can successfully decode the received sequence without any risk. In an exemplary embodiment, the OFDM codeword size and duration control module can be configured to reduce duration of OFDM codeword. Removal of symbols from OFDM codeword results in shortened codeword of duration lesser than the duration of the original OFDM codeword or codeword with lesser symbols but of same duration as the original OFDM codeword before removal of symbol.

In an exemplary embodiment, the OFDM redundancy based error correction module 206 can be configured to correct error present in the received sequence using the OFDM redundancy in OFDM scheme that have inherent redundancy, for example due to IFFT matrix and FFT matrix.

The OFDM redundancy trade-off module 208 can be configured to enable trade-off between ODFM redundancy and other redundancies available in the system. The ODFM redundancy trade-off module 208 can be configured to trade-off redundancy due to one or more of cyclic prefix, OFDM codeword size duration, PAPR, (N, K) block code etc. The OFDM redundancy trade-off module 208 can include exemplary modules such as a PAPR trade-off module 210 that can be configured to trade-off redundancy due to PAPR minimiser, a (N,K) block code trade-off module 212 that can be configured to reduce N, preferably make N=K, and a cyclic prefix trade-off module 214 that can be configured to control size of cyclic prefix.

In an aspect, the cyclic prefix trade-off module 214 can be configured to control size of cyclic prefix, for instance by reducing/increasing size of cyclic prefix, or enabling or disabling cyclic prefix.

One or more modules of the system can be implemented by a redundancy controller that can be configured to control redundancy due to (n,k) encoder/decoder, PAPR minimizer/reversal, addition/removal of Cyclic Prefix, removal of symbols from OFDM codeword and OFDM code word decoder.

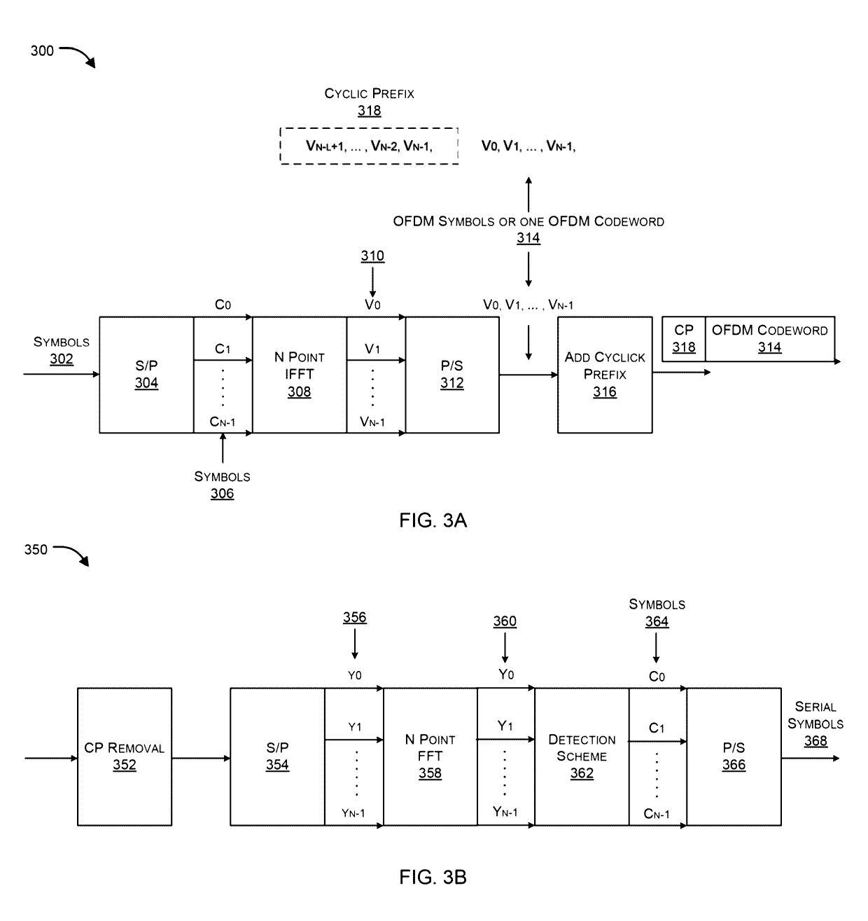

FIG. 3A illustrates exemplary functional blocks of a transmitter configured to perform OFDM coded transmission in accordance with an embodiment of the present disclosure. FIG. 3B illustrates an exemplary functional blocks of a receiver configured to receive sequence and generate corrected information sequence in accordance with an embodiment of the present disclosure. The transmitter and receiver as shown in the FIGS. 3A and 3B can be configured to determine channel quality and use the redundancy of the OFDM scheme to trade off the redundancy due to cyclic prefix, PAPR redundancy and similar other redundancy present in the communication system.

Contemporary OFDM based communication system can use the components as shown in FIG. 3A and FIG. 3B. Existing systems never used redundancy built within the IFFT and FFT matrix of the OFDM transmission scheme. Embodiments of the present disclosure aim to use the inherent redundancy of the OFDM transmission scheme. FIG. 3A shows sequence of operations performed by different components at transmitter side. As shown in FIG. 3A, a sequence of symbols 302, which can be the data to be transmitted to a receiver from a transmitter can be converted from a serial form of data to parallel symbols C=(C₀, C₁, . . . , C_{N-1}) 306 by S/P block 304 if required. These N parallel symbols C=(C₀, C₁, . . . , C_{N-1}) 306 can be processed by N point IFFT 308 to a get an information sequence V=(V₀, V₁, . . . , V_{N-1}) 310 that can be transformed by parallel to serial P/S block 312 to get a transformed information sequence 314, also referred interchangeably as OFDM codeword 314 for sending it over a suitable transmission channel to a receiver. Depending on the channel quality estimation, transmitter can add cyclic prefix (CP) 316 with the OFDM codeword 214 before transmitting symbols over the transmission channel. If the transmitter generates OFDM codeword, the receiver performs the reverse operation. FIG. 3B illustrates sequence of operations performed by different components at receiver side. On receiving the symbols, the CP removal 352 can remove the cyclic prefix 318 as added by the transmitter and send the symbols that is in sequential form to a S/P block 354 to generate the OFDM sequence y=(y₀, y₁, . . . , y_{N-1}) 356. The ODFM sequence 356 can be processed by N point FFT 358 to get the estimated information sequence Y=(Y₀, Y₁, . . . , Y_{N-1}) 260. Error detection scheme 262 can generally be used to determine error present in the estimated information sequence Y 260. Error present in the estimated information sequence Y 256 can be corrected based on the error correction capability of the system using the redundancy added at different stages at the transmitter. The existing systems use (n,k) block, cyclic prefix etc. to add some redundancy in the system so that the error can be corrected at the receiver side. Most of the existing systems don't use the redundant information present in the received sequence y=(y₀, y₁, . . . , y_{N-1}). This is analogous to not using the parity-check bits of (n,k) block code for performing error.

In a typical OFDM scheme, a band of baseband frequency can be divided into multiple channels, say N number of channels, such that the center frequency of each channel is harmonic to the center frequency of the first channel, i.e. the fundamental frequency. Each of the harmonics is called as sub-carrier. It can be verified that sinusoid of one sub-carrier frequency is orthogonal to sinusoid of another sub-carrier frequency. This orthogonality enables simple equalization at the receiver. Data can be converted into N parallel streams and symbol in each stream can modulate exactly one of the N sub-carriers. N such symbols will modulate N sub-carriers simultaneously, for exactly N symbol duration, and combined or added to get an analog or continuous wave signal that has exactly N sub-carriers as its frequency components. At the receiver, reverse operation can be performed. In discrete time domain, such OFDM systems can be implemented using N-by-N DFT and N-by-N IDFT operations that are, for practical reasons implemented using N-by-N FFT and N-by-N IFFT blocks as shown in FIG. 3A and FIG. 3B. As one may appreciate, each symbol of an OFDM codeword can be and has been referred as OFDM symbol interchangeably in this document.

When OFDM transmission is represented as IDFT (or IFFT), each column of the N-by-N IDFT (or IFFT) matrix are independent. Similar observation can be made when OFDM reception is represented as DFT (or FFT). That is, no column of IDFT and DFT matrix can be written as linear combination of all the other columns. Similarly, no row of IDFT and DFT matrix can be written as linear combination of all other rows. Another way to appreciate independence is to notice that the Discrete Time representation of IDFT and DFT is generated from N orthogonal frequencies by translating or transforming the orthogonality (and corresponding independence because orthogonality implies independence) in frequency domain to N-point discrete-time domain representation. As one may appreciate, orthogonality to one domain is invariant in another transformed domain. As observed, when any column can be written as linear combination of certain number of columns, the minimum distance dₘᵢₙ is exactly equal to those number of columns, subject to decimal or normal addition. In case of N-by-N IDFT or DFT matrix, the minimum distance can be given as dₘᵢₙ=N, subject to decimal or normal addition, as there are N columns and N rows. This means that OFDM based systems can correct N−1/2 errors, if such OFDM systems are used for error correction.

Error correction capability of OFDM can be illustrated with N-by-N IDFT matrix, say G*_{OFDM}. G*_{OFDM} that is a complex conjugate of G_{OFDM}, where, each element of G_{OFDM} has a complex number representation. For example, k^{th} column of G_{OFDM} can be G_{OFDM}(k)=[W^{0×k}W^{1×k}W^{2×k} . . . W^{(N-1)×k}]^{T}, where

$$W = {e}^{\frac{i 2 π}{N}} = cos ( \frac{2 π}{N} ) + i sin ( \frac{2 π}{N} ) and 0 \leq k \leq N - 1.$$

### For N=2,

$${G}_{OFDM} = [ \begin{matrix}1 & 1 \\ 1 & - 1\end{matrix} ] .$$

### For N=3,

$${G}_{OFDM} = [ \begin{matrix}1 & 1 & 1 \\ 1 & - 0.5 + 0.8660254 i & - 0.5 - 0.8860254 i \\ 1 & - 0.5 - 0.8660254 i & - 0.5 + 0.8860254 i\end{matrix} ] .$$

### For N=4,

$${G}_{OFDM} = [ \begin{matrix}1 & 1 & 1 & 1 \\ 1 & i & - 1 & - i \\ 1 & - 1 & 1 & - 1 \\ 1 & - i & - 1 & i\end{matrix} ]$$

As shown in FIG. 3A and FIG. 3B, G_{OFDM} can be used at the OFDM receiver and complex conjugate of G_{OFDM}, that is G*_{OFDM}, which can be used at the transmitted. (Symmetry along the diagonal means that transpose of G_{OFDM} and G*_{OFDM} are same as the matrices G_{OFDM} and G*_{OFDM}.) If an N-tuple codeword C=(c₀, c₁, . . . , c_{N-1}) is to be transmitted over the channel, then after multiplication with G*_{ODFM} an N-tuple sequence of symbols or codeword 310, V=(v₀, v₁, . . . , v_{N-1})=C×G*_{OFDM} can be generated. Each element of codeword V 310 can be configured to work both as a signal as well as a symbol. Elements cᵢ are complex symbols for 0≦i≦N−1. (If cᵢ takes values 0 or 1, then C becomes a Hamming Code, C_{H}.) If element cᵢ is a BPSK (Binary Phase-Shift Keying) symbol then in binary they have values 0 or 1. But, in complex symbol or signal representation, a binary 0 (zero) can be represented as −1 volt and binary 1 (one) can be represented as +1 volt. As we know, for any physical transmission, the codeword must be represented in complex signal notation. If the element cᵢ is from 16-QAM constellation, then in binary they will have sequences (0 0 0 0), (0 0 0 1), . . . , (1 1 1 1). But in complex signal notation (0 0 0 0) will be represented as (−\sqrt{E},−\sqrt{E}) and so on for other; where \sqrt{E} is energy per symbol. Here one symbol from 16-QAM constellation is transmitted with energy \sqrt{E} in place of four bits (0 0 0 0).

For N=2,

$${G}_{OFDM}^{*} = [ \begin{matrix}1 & 1 \\ 1 & - 1\end{matrix} ] .$$

If the transmitter wants to transmit 2-tuple binary codeword, say C=(0 0) as an OFDM codeword, then C can be first converted to BPSK symbol to (−1 −1), and then multiplied with G_{OFDM} to generate an OFDM codeword. The generated OFDM codeword can be (−2 0). This OFDM codeword can act both as a signal and a codeword. The Error! Reference source not found. lists the generated OFDM codewords for all combinations of 2-tuple binary codeword. It is to be understood that this codeword is not codeword are per the definition we provided in the beginning. Here codeword and message are same. Other examples will be more practical.

TABLE 1
Generation of OFDM codeword for
N = 2 for 2-tuple binary codeword

| Binary codeword | BPSK codeword | OFDM codeword |
|---|---|---|
| (0 0) | (−1 −1) | (−2 0) |
| (0 1) | (−1 1) | (0 −2) |
| (1 0) | (1 −1) | (0 2) |
| (1 1) | (1 1) | (2 0) |

In present instance, each bit of the BPSK codeword is of unit power where power envelop is constant, whereas the OFDM codeword requires different power to transmit each OFDM symbol. For each codeword power to transmit, the first OFDM symbol can be different than the second OFDM symbol and hence the power envelop can't be constant. Also in case of OFDM codeword, there is no transmission for certain symbol. The Power Amplifier will be very inefficient for about 50% of the time due to 50% period of inactivity or non-transmission.

OFDM redundancy can be highlighted with help of another example where N=7. Due to long length of the matrix G*_{OFDM} we will only illustrate the seven columns of G*_{OFDM}.

$${G}_{OFDM}^{*} ( 0 ) = {( 1 , 1 , 1 , 1 , 1 , 1 , 1 )}^{T}$$

$${G}_{OFDM}^{*} ( 1 ) = {( \begin{matrix}1 , & 0.6234898 - 0.7818315 i , \\ - 0.2225209 - 0.9749279 i , & - 0.9009689 - 0.4338837 i , \\ - 0.9009689 + 0.4338837 i , & - 0.2225209 + 0.9749279 i , \\ 0.6234898 + 0.7818315 i & \end{matrix} )}^{T}$$

$${G}_{OFDM}^{*} ( 2 ) = {( \begin{matrix}1 , & - 0.2225209 - 0.9749279 i , \\ - 0.9009689 + 0.4338837 i , & 0.6234898 + 0.7818315 i , \\ 0.6234898 - 0.7818315 i , & - 0.9009689 - 0.4338837 i , \\ - 0.2225209 + 0.9749279 i & \end{matrix} )}^{T}$$

$${G}_{OFDM}^{*} ( 3 ) = {( \begin{matrix}1 , & - 0.2225209 - 0.9749279 i , \\ - 0.9009689 + 0.4338837 i , & 0.6234898 + 0.7818315 i , \\ 0.6234898 - 0.7818315 i , & - 0.9009689 - 0.4338837 i , \\ - 0.2225209 + 0.9749279 i & \end{matrix} )}^{T}$$

$${G}_{OFDM}^{*} ( 4 ) = {( \begin{matrix}1 , & - 0.9009689 + 0.4338837 i , \\ 0.6234898 - 0.7818315 i , & - 0.2225209 + 0.9749279 i , \\ - 0.2225209 - 0.9749279 i , & 0.6234898 + 0.7818315 i , \\ - 0.9009689 - 0.4338837 i & \end{matrix} )}^{T}$$

$${G}_{OFDM}^{*} ( 5 ) = {( \begin{matrix}1 , & - 0.2225209 + 0.9749279 i , \\ - 0.9009689 - 0.4338837 i , & 0.6234898 - 0.7818315 i , \\ 0.6234898 + 0.7818315 i , & - 0.9009689 + 0.4338837 i , \\ - 0.2225209 - 0.9749279 i & \end{matrix} )}^{T}$$

$${G}_{OFDM}^{*} ( 6 ) = {( \begin{matrix}1 , & 0.6234898 + 0.7818315 i , \\ - 0.2225209 + 0.9749279 i , & - 0.9009689 + 0.4338837 i , \\ - 0.9009689 - 0.4338837 i , & - 0.2225209 - 0.9749279 i , \\ 0.6234898 - 0.7818315 i & \end{matrix} )}^{T}$$

For an exemplary input codeword generated by a (N,K) block code, say (7,4) linear block code, BPSK codeword as shown in Table-2 can be generated.

TABLE 2
binary to BPSK codeword conversion and then to
OFDM codeword conversion for (7,4) block code.

| (7,4) codeword | BPSK codeword | OFDM codeword |
|---|---|---|
| (0 0 0 0 0 0 0) | (−1−1−1−1−1−1−1) | (−7, 0, 0, 0, 0, 0, 0) |
| (1 1 0 1 0 0 0) | (1 1 −11 −1−1−1) | (−1, 1.4450419 − 2.4314304i, |
| | | 2.8019377, −2.8176233i, |
| | | 2.8176233i, 2.8019377, |
| | | 1.4450419 + 2.4314304i) |
| (0 1 1 0 1 0 0) | (−1 1 1 −11 −1−1) | (−1, −2.6457513i, −2.6457513i, −1 + |
| | | 2.6457513i, −2.6457513i, −1 + |
| | | 2.6457513i, −1 + 2.6457513i) |
| (1 0 1 1 1 0 0) | (1 −1 1 1 1 −1−1) | (1, −2.0489173 − 1.9498558i, |
| | | 2.6920215, 2.3568959 + 1.563663i, |
| | | 2.3568959 − 1.563663i, |
| | | 2.6920215, −2.0489173 + 1.9498558i) |
| (1 1 1 0 0 1 0) | (1 1 1 −1 −1 1 −1) | (1, 2.3568959 − |
| | | 1.563663i, −2.0489173 − 1.9498558i, |
| | | 2.6920215, 2.6920215, −2.0489173 + 1.9498558i, |
| | | 2.3568959 + 1.5636653i) |
| (0 0 1 1 0 1 0) | (−1−1 1 1 −11 −1) | (−1, −2.6920215, −2.3568959 + |
| | | 1.563663i, 2.0489173 − 1.9498558i, |
| | | 2.0489173 + 1.9498558i, −2.3568959 − |
| | | 1.563663i, −2.6920215) |
| (1 0 0 0 1 1 0) | (1 −1−1−11 1 −1) | (−1, 2.8176233i, 1.4450419 − 2.4314304i, |
| | | 2.8019377, 2.8019377, 1.4450419 + |
| | | 2.4314304i, −2.8176233i) |
| (0 1 0 1 1 1 0) | (−1 1 −1 1 1 1 −1) | (1, −2.8019377, −2.8176233i, −1.4450419 − |
| | | 2.4314304i, −1.4450419 + 2.4314304i, |
| | | 2.8176233i, −2.8019377) |
| (1 0 1 0 0 0 1) | (1 −1 1 −1−1−1 1) | (−1, 2.8019377, 2.8176233i, 1.4450419 + |
| | | 2.4314304i, 1.4450419 − 2.4314304i, −2.8176233i, |
| | | 2.8019377) |
| (0 1 1 1 0 0 1) | (−1 1 1 1 −1 −1 1) | (1, −2.8176233i, −1.4450419 + |
| | | 2.4314304i, −2.8019377, −2.8019377, −1.4450419 − |
| | | 2.4314304i, 2.8176233i) |
| (1 1 0 0 1 0 1) | (1 1 −1−1 1 −1 1) | (1, 2.6920215, 2.3568959 − 1.563663i, −2.0489173 + |
| | | 1.9498558i, −2.0489173 − 1.9498558i, 2.3568959 + |
| | | 1.563663i, 2.6920215) |
| (0 0 0 1 1 0 1) | (−1 −1−1 1 1 −1 1) | (−1, −2.3568959 + 1.563663i, 2.0489173 + |
| | | 1.9498558i, −2.6920215, −2.6920215, 2.0489173 − |
| | | 1.9498558i, −2.3568959 − 1.563663i) |
| (0 1 0 0 0 1 1) | (−1 1 −1−1−11 1) | −(1, 2.0489173 + |
| | | 1.9498558i, −2.6920215, −2.3568959 − |
| | | 1.563663i, −2.3568959 + 1.563663i, −2.6920215, |
| | | 2.0489173 − 1.9498558i) |
| (1 0 0 1 0 1 1) | (1 −1 −1 1 −11 1) | (1, 2.6457513i, 2.6457513i, 1 − 2.6457513i, |
| | | 2.6457513i, 1 − 2.6457513i, 1 − 2.6457513i) |
| (0 0 1 0 1 1 1) | (−1−1 1 −1 1 1 1) | (1, −1.4450419 + 2.4314304i, −2.8019377, |
| | | 2.8176233i, −2.8176233i, −2.8019377, −1.4450419 − |
| | | 2.4314304i) |
| (1 1 1 1 1 1 1) | (1 1 1 1 1 1 1) | (7, 0, 0, 0, 0, 0, 0) |

As shown in Table-2, the 7-tuple OFDM codeword can be generated for (7,4) codeword. As can be observed, each OFDM code word can have sufficient Euclidean distance between any other OFDM codeword and also unique. Therefore, for decoding possible transmitted OFDM codeword from the received sequence, we can use Euclidean distance as one method. Other methods known in known in the literature can also be used by the system and method of the present disclosure. Once the transmitted OFDM codeword is decoded, a look in the table will point at the transmitted (7,4) codeword. Alternatively, the receiver after removal of any cyclic prefix can subsequently perform FFT operation 358 to get the transmitted BPSK codeword 360, and then using threshold detection or Signum function, the transmitted (7,4) codeword can be decoded. Any additional error can be corrected by the (7,4) codeword to obtain the transmitted message or information sequence.

As can be observed, if the transmitter transmits the codeword C, absolute value of cᵢ, 0≦i≦6, will be transmitted. As can be seen, the absolute value of cᵢ is always \sqrt{E}. This means the power envelop is constant. Whereas when we transmit the OFDM codeword, V, the absolute value of vᵢ, 0≦i≦6, is not constant. The corresponding transmitted power does not have a constant envelope and includes variations. This variation means that there is at least one peak value and an average value. This variation results in Peak Power to Average Power (PAPR) ratio being significantly more than unity or one. This PAPR issue can also have notorious disadvantage on OFDM transmission as the RF Power Amplifier backs-off for every transmission of vᵢ and is therefore the primary cause for energy inefficiency in OFDM based radio communication, e.g. OFDMA and SC-FDMA. Various arts are known that focus on system design to make the PAPR approach one.

It has been observed that N columns of G_{OFDM} are independent and therefore the minimum distance dₘᵢₙ is N. Therefore the error-correction capabilities of a ODFM transmission code scheme of present disclosure can be

$${t}_{OFDM} \leq \frac{N - 1}{2} .$$

This means that if N=1024, then OFDM can correct t_{OFDM}≦511.5 errors. This independence can also be intuitively appreciated by observing that the summation of element-by-element multiplication of C×G_{OFDM} to generate V is generally in decimal domain and not in binary domain or modulo-2. The decimal summation and independence of the columns makes the OFDM systems have high PAPR and highly redundant. In exemplary embodiments, correction of errors using the OFDM redundancy can be performed using Maximum Likelihood Decoding, Maximum Logic Decoding, Minimum Mean Square Error, Minimum Euclidean Distance, Iterative Decoding, etc.

### Trade-Off PAPR

The system and method of present disclosure can be configured to switch transmission between high PAPR and low PAPR transmission using the redundancy of ODFM scheme. The OFDM transmission can be configured to take advantage of inherent redundancy present in the OFDM scheme, due to its orthogonal nature and IFFT and FFT matrix, for controlling the PAPR.

### Trade-Off Cyclic Prefix

It has been observed that OFDM scheme has inherent redundancy of at least 50%. For all zero or all one codeword, the corresponding OFDM codeword has more than 50% redundancy. The observation can be verified by observing that highest peak power (and PAPR per codeword) occurs for these two codewords. Because of this redundancy, in the OFDM scheme, the system and method of present disclosure can be configured to replace some of the last few columns by cyclic prefixes. This will avoid overheads due to cyclic prefix in OFDM based communication systems.

The error correction capability of the ODFM coded transmission system of present disclosure can be illustrated with an example as below. Taking the example with respect to (7,4) block code that can to be transmitted as OFDM symbol as show in Table 2. If the codeword is (1 1 0 1 0 0 0), the transmitted OFDM symbol V is (−1, 1.4450419−2.4314304i, 2.8019377, −2.8176233i, 2.8176233i, 2.8019377, 1.4450419+2.431430i). Assuming that the received OFDM symbol has three symbols with error in last three positions. The receiver has received sequence as y=(−1, 1.4450419−2.431430i, 2.8019377, −2.8176233i, Error 1, Error 2, Error 3), where Error 1, Error 2 and Error 3 are any type of errors. Without knowledge of power of these three errors, the present disclosure is able to decode the transmitted OFDM codeword V. From Error! Reference source not found., we locate codeword that has first symbol same as −1, that is y₀=v₀. There are 7 such OFDM codewords, including the transmitted OFDM codeword:
1) (−1, 1.4450419−2.4314304i, 2.8019377, −2.8176233i, 2.8176233i,2.8019377,1.4450419+2.4314304i)—The first four symbols are same as received sequence
2) (−1, −2.6457513i,−2.6457513i, −1+2.6457513i, −2.6457513i, −1+2.6457513i, −1+2.6457513i)
3) (−1, −2.6920215, −2.3568959+1.563663i, 2.0489173−1.9498558i, 2.0489173+1.9498558i, −2.3568959−1.563663i, −2.6920215)
4) (−1, 2.8176233i, 1.4450419−2.4314304i, 2.8019377, 2.8019377, 1.4450419+2.4314304i, −2.8176233i)
5) (−1, 2.8019377, 2.8176233i, 1.4450419+2.4314304i, 1.4450419−2.4314304i, −2.8176233i, 2.8019377)
6) (−1, −2.3568959+1.563663i, 2.0489173+1.9498558i, −2.6920215, −2.6920215, 2.0489173−1.9498558i, −2.3568959−1.563663i)
7) (−1, 2.0489173+1.9498558i, −2.6920215, −2.3568959−1.563663i, −2.3568959+1.563663i, −2.6920215,2.0489173−1.9498558i)

Ignoring last three symbol positions of these OFDM codewords, and finding lowest symbol-by-symbol Euclidean distance with respect to the received sequence, the transmitted OFDM codeword can be decoded correctly. In this case, the receiver can decode as (−1, 1.4450419−2.4314304i, 2.8019377, −2.8176233i, 2.8176233i, 2.8019377, 1.4450419+2.4314304i) which was the right codeword sent by the transmitter.

### Trade-Off Redundancy of Block Code

Moreover, High PAPR OFDM codewords can be optimized for better control in power, error tolerance and overhead. Also, the codeword C that generates OFDM codeword V 310 also has redundancy in the form of redundant bits due to the coding technique used to obtain symbols C 306 from the message bits 302. In which case symbols C 306 will have error correction capability that can be given by its minimum distance d_{min,C}. Codeword C can correct

$${t}_{C} \leq \frac{{d}_{min , C} - 1}{2}$$

errors. If OFDM has minimum distance d_{min,OFDM}, then together C and V will have minimum distance d_{min,C}×d_{min,OFDM}. Therefore total number of errors that can be corrected is

$${t}_{total} \leq \frac{{d}_{min , C} \times {d}_{min , OFDM} - 1}{2} .$$

For example, if d_{min,C}=3 and d_{min,OFDM}=1024, then

$$\frac{3 \times 1024 - 1}{2} = 1535$$

errors can be corrected by the system of present disclosure. Also if d_{min,C}=1 and d_{min,OFDM}=1024, then

$$\frac{1 \times 1024 - 1}{2} = 511$$

errors can be corrected solely based on OFDM redundancy.

The transmitter and receiver as shown in FIGS. 3A and 3B can be configured to use redundancy built in the IFFT and FFT matrix and trade-off with other redundancy available in the communication system. For example, the redundancy due to N point IFFT 208 can be used to be trade-off with the redundancy of due to add cyclic prefix S/P 304, redundancy of PAPR, and redundancy due to add cyclic prefix 316.

The OFDM coded transmission system of present disclosure can be configured to use redundancy of OFDM scheme to trade-off the redundancy being introduced at other places in the system. In an embodiment, system of the present disclosure can be configured to reduce the ODFM codeword size and duration for the symbols being transmitted by the transmitter. In an embodiment, the ODFM coded transmission system of the present disclosure can be configured to trade-off redundancy due to one or more of cyclic prefix, OFDM codeword size and duration, PAPR, (N,K) block code etc. with each other. The transmitter and receiver can be configured to mutually negotiate and agree about various actions, such as enabling/disabling cyclic prefixes, reducing OFDM codeword size, configuration of (N,K) block codes, configuration PAPR etc, taken by system before transmission of message.

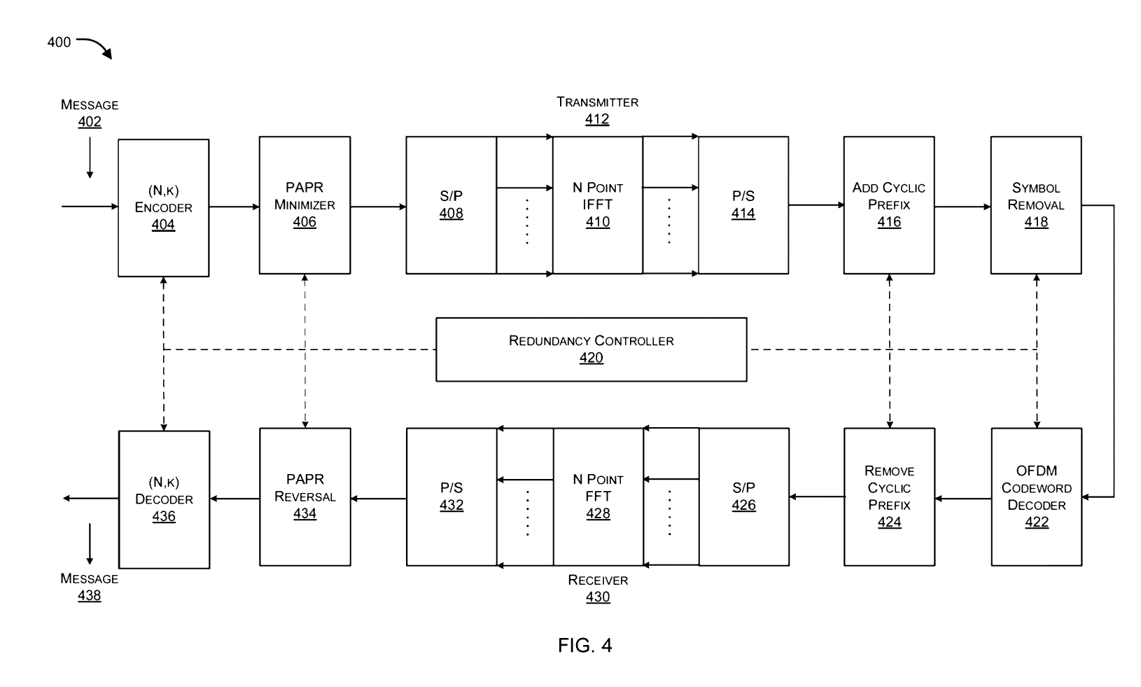

FIG. 4 illustrates a high level architecture of the OFDM coded transmission employing a redundancy controller 420 in accordance with an embodiment of the present disclosure. The architecture 400 for enabling communication between a transmitter 412 and a receiver 430 can include a redundancy controller 420 that can be configured to trade-off and control redundancy due to (n,k) encoder/decoder, PAPR minimizer/reversal, cyclic prefix, removal of symbols from OFDM codeword and OFDM codeword decoder. The transmitter 412 and receiver 430 can be connected through a suitable channel. The transmitter 412 may include a (N,K) encoder 404 for encoding a message block 402 of K symbols/bits to form a encoded N bit symbols, a PAPR minimizer 406 configured to process the encoded symbols to minimize the PAPR of the OFDM codeword transmitted over the channel. The encoded symbols can be converted from serial to parallel by S/P block 408. The transmitter 412 can perform N point IFFT 410, which has inherent redundancy, to transform the encoded symbols into information sequence/ODFM codeword that can be converted into serial form by a P/S block 414. The transmitter can be configured to add cyclic prefix 416 with the OFDM codeword before the symbols are transmitted over the transmission channel. In an exemplary embodiment, depending on the channel quality estimation, the transmitter can determine the redundancy requirement of the communication channel and trade-off and control redundancies introduced by the transmitter at different stage. In an exemplary embodiment, the transmitter 412 can include a symbol removal 418 that can be configured to reduce the codeword size and duration. The transmitter can transmit the ODFM codeword with reduced codeword size to the receiver 430. In an exemplary embodiment, the receiver 430 can have an OFDM codeword decoder configured to decode the received sequence, a remove cyclic prefix block 424 configured to remove cyclic prefix to get estimated ODFM symbols. The estimated ODFM symbols can be converted from parallel stream to serial by an S/P block 426 and can be processed by an N-point FFT 428. The receiver can also include a P/S block 432 to convert the parallel data steam in serial. The receiver 430 can include a PAPR reversal 434 that can remove the processing performed by PAPR Minimizer 406 for maintaining PAPR and a (N,K) decoder 436 that can convert the symbols into message 438. In an exemplary embodiment, the PAPR minimizer 406 and PAPR reversal 434 can be performed by any known methods.

In an exemplary embodiment, the ODFM coded transmission system of present disclosure can include a redundancy controller 420, which controller 420 can be configured to enable trade-off between different redundancies available in communication system. The redundancy controller 420 can be configured to trade-off redundancy due to one or more of cyclic prefix, OFDM codeword size & duration, PAPR, (N,K) block code etc. with each other. The redundancy controller 420 can be configured to enable negotiation and agreement between the transmitter 412 and receiver 420 about various actions, such as enabling/disabling cyclic prefixes, reducing OFDM codeword size, configuration of (N,K) block codes, configuration PAPR etc, taken by system before transmission of message. The redundancy controller 420 can be configured to trade-off redundancy of the OFDM scheme with other redundancies in the communication system based on channel quality estimation.

In an exemplary embodiment, the redundancy controller 420 can enable or disable cyclic prefix. In another exemplary embodiment, if high redundancy is not required from (n,k) encoder/decoder then redundancy controller 420 can make n=k. Yet in another exemplary embodiment, the redundancy controller can be configured to control the number of OFDM symbols to be used for transmission of the OFDM codeword such that OFDM codeword decoder can successfully decode the OFDM codeword without any risk. Removal of symbols from OFDM codeword results in shortened codeword of duration lesser than the duration of the original OFDM codeword or codeword with lesser symbols but of same duration as the original OFDM codeword before removal of symbol.

Various actions taken by the redundancy controller 420 at the transmitter can be negotiated with the redundancy controller at the receiver before transmission of message.

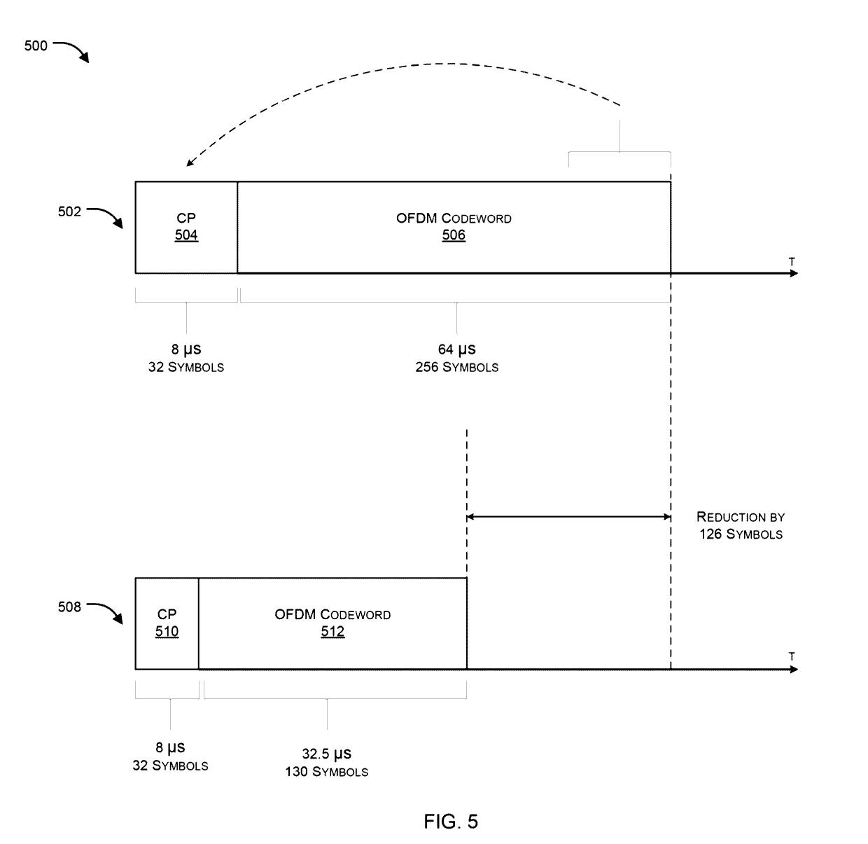

FIG. 5 illustrates an exemplary case of reduced codeword size for the OFDM coded transmission achieved in accordance with an embodiment of the present disclosure. Size of OFDM codeword and its duration can be controlled by the system and/or redundancy controller of present disclosure. For example, if a regular OFDM transmission 502 includes a cyclic prefix CP of 32 symbols 504 and OFDM codeword 506 of 256 symbols, the system and/or controller of present disclosure can be configured to reduce the size of OFDM codeword by 126 symbols and make the OFDM codeword 512 with 130 symbols. The reduction of codeword size can be based on channel quality. In an exemplary embodiment, the controller or system of present disclosure can trade-off and quantify the size of OFDM codeword based on the channel quality and by using redundancy of OFDM scheme. The system and controller of present disclosure in the present illustration improves network utilization by 126 OFDM symbols. An exemplary advantage of the present disclosure can be understood with below example explained with reference to the FIG. 5. For instance, consider one of the several profiles defined in WiMAX (Wireless interoperability of Microwave Access) standard which is a fixed profile. The fixed profile uses N=256 sub-carriers. The sub-carrier bandwidth is B_s=15.625 kHz. For this profile, OFDM codeword time (without cyclic prefix) is equal to 1/B_s=64 μs. There are N=256 symbols in 64 μs. The amount of cyclic prefix can be 12.5% of the OFDM codeword time, which being equal to 12.5/100×64 μs=8 μs. As can be seen, there are 32 OFDM symbols in 8 μs cyclic prefix 504. The cyclic prefix 504 is added to prevent inter-codeword-interference. The system and controller of present disclosure aims to use redundancy in OFDM codeword by (N−1)/2=(256−1)/2=127.5 symbols. The symbol removal block of the system can remove 126 symbols from the OFDM codeword, then the new OFDM Codeword 512 of length 130 symbols will still have redundancy of 2.5 OFDM symbols. As one may appreciate, the system retains the same number of symbols (32 symbols) for cyclic prefix as the length of cyclic prefix depends on the delay spread that causes inter-codeword-interference. If the channel was good and no symbol error happened during transmission, then the OFDM codeword decoder will be able to recreate the transmitted OFDM Codeword of length 256 symbols, from the received OFDM sequences of 32+130=162 symbols, that was provided as input to the OFDM symbol removal. Due to addition of cyclic prefix, the loss in spectral efficiency in first case 502, where OFDM codeword of 256 with CP of 32 symbols is transmitted, is 32/(32+256)=11.1%, and in second case 508 where OFDM codeword of 130 symbols with CP of 32 symbols is transmitted, the loss in spectral efficient is 32/(32+130)=19.8%. However, the overall improvement in spectral efficiency due to OFDM symbol removal and OFDM codeword decoder for (B) is (288−162)/288=43.8%. As one may appreciate, in present illustration, the system has used redundancy in OFDM codeword to improve the network utilization by 43.8%. If the channel is bad, then we can trade this improvement in network utilization to send more OFDM symbols, that is, remove less number of OFDM symbols from the OFDM codeword at the OFDM symbols removal. One may also appreciate that the system has achieved the efficiency without using block code redundancy, if any.

Though, most of the embodiment of the present disclosure has been illustrated with respect to communication system, the teaching of present disclosure can for obtaining efficient in the storage system.

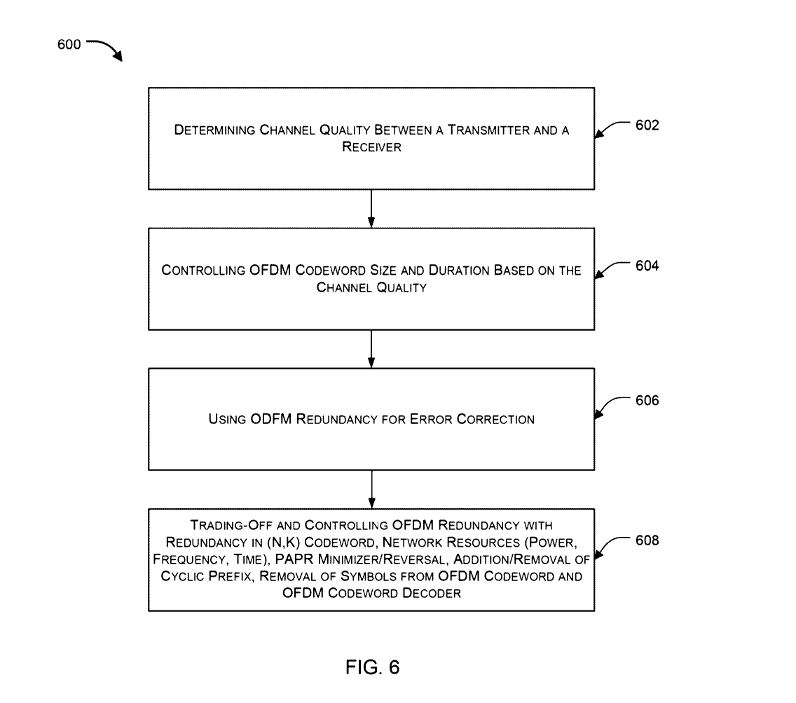

FIG. 6 illustrates an exemplary flow diagram of a method for OFDM coded transmission in accordance with an embodiment of the present disclosure. The method makes use of redundancy of the OFDM transmission scheme (IFFT matrix and FFT matrix) to control and/or trade-off with other redundancies in a communication system. The method includes steps of determining, at step 602, channel quality between a transmitter and a receiver, controlling, at step 604, OFDM codeword size and duration based on the channel quality, using, at step 606, ODFM redundancy for error correction, and trading-off and controlling, at step 608, OFDM redundancy with redundancy in (n,k) codeword, network resources (power, frequency, time), PAPR minimizer/reversal, addition/removal of Cyclic Prefix, removal of symbols from OFDM codeword and OFDM codeword decoder.

In an exemplary embodiment, the method can be configured to estimate the channel quality between a transmitter and receiver using the beacon based quality estimation technique.

Based on the estimated channel quality, the method can determine the amount of redundancy required for optimal communication between the transmitter and receiver. In an exemplary implementation, if the channel quality is good, the transmission and reception have the message can be performed with less redundancy in the system. Based on the estimated channel quality, the method can be configured to trade-off redundancy of OFDM scheme with other redundancies available in the system. In an exemplary implementation, the OFDM codeword size and duration cm be controlled based on the estimated channel quality. For example, if the channel quality is good, the method can enable communication with reduced symbols size and duration.

In an exemplary embodiment, the method can be configured to control the number of OFDM symbols that needs to be used to transmit OFDM codeword such that OFDM codeword decoder can successfully decode the OFDM codeword without any risk. In an exemplary embodiment, the OFDM codeword size and duration control can reduce duration of OFDM codeword. Removal of symbols from OFDM codeword results in shortened codeword of duration lesser than the duration of the original OFDM codeword or codeword with lesser symbols but of same duration as the original OFDM codeword before removal of symbol.

In an exemplary embodiment, the method can be configured to correct error present in the received sequence, using the OFDM redundancy in OFDM scheme that have inherent redundancy, for example due to IFFT matrix and FFT matrix. The method can further be configured to enable trade-off between ODFM redundancy and other redundancies available in the system. The method can be configured to trade-off redundancy due to one or more of cyclic prefix, OFDM codeword size duration, PAPR, (N,K) block code etc.

The one or more steps of method described above can be implemented by a redundancy controller that can be configured to control redundancy due to (n,k) encoder/decoder, PAPR minimizer/reversal, addition/removal of Cyclic Prefix, removal of symbols from OFDM codeword and OFDM codeword decoder.

While the foregoing describes various embodiments of the invention, other and further embodiments of the invention may be devised without departing from the basic scope thereof. The scope of the invention is determined by the claims that follow. The invention is not limited to the described embodiments, versions or examples, which are included to enable a person having ordinary skill in the art to make and use the invention when combined with information and knowledge available to the person having ordinary skill in the art.

### ADVANTAGE OF THE INVENTION

The present disclosure provides systems and methods for ODFM coded transmission with optimal redundancy in the transmitted codeword.

The present disclosure provides systems and methods of ODFM coded transmission with optimal redundancy in the transmitted codeword, without compromising the error correction capabilities of the communication system.

The present disclosure provides systems and methods that can change codeword size of ODFM codeword dynamically based on channel condition.

The present disclosure systems and methods that can determine the required redundancy in communication and trade-off redundancies created at different places.

The present disclosure provides systems and methods for OFDM code transmission and reception without requiring addition of any cyclic prefix.

The present disclosure provides systems and methods for OFDM coded transmission that can enable or disable usage of cyclic prefix.

The present disclosure provides system and method for OFDM coded transmission, for improved communication efficiency by reducing N, preferably making, N=k for a (N,K) block code, without reducing the error correction capability of the communication system.

The present disclosure provides systems and methods for OFDM coded transmission with improved spectral efficient.

What is claimed is:

1. A system for enabling OFDM coded transmission and reception, said system comprising a transmitter and a receiver coupled with each other through a transmission channel, wherein said system further comprises:
a channel quality estimation module configured to determine quality of the transmission channel between the transmitter and the receiver; and
an OFDM redundancy trade-off module configured to determine required redundancy in Orthogonal frequency-division multiplexing (OFDM) scheme based on the determined channel quality, and trade off the redundancy in the OFDM scheme with redundancy in any or a combination of (n,k) block code, power-based network resources, frequency-based network resources, time-based network resources, Peak-to-Average Power Ratio (PAPR) minimizer/reversal, Cyclic Prefix, removal of symbols from OFDM codeword and OFDM codeword decoder, in order to achieve the required transmission redundancy.

2. The system of claim 1, wherein the system further comprises an OFDM codeword size and duration control module configured to trade-off OFDM codeword size and duration based on the required OFDM redundancy for transmission of OFDM codeword.

3. The system of claim 2, wherein the OFDM codeword size and duration control module is further configured to control number of OFDM symbols to be used for transmitting the OFDM codeword such that OFDM codeword decoder successfully decodes the OFDM codeword.

4. The system of claim 2, wherein the OFDM codeword size and duration control module is further configured to remove OFDM symbols required for transmission of the OFDM codeword.

5. The system of claim 2, wherein the OFDM codeword size and duration control module is further configured to reduce duration of the OFDM codeword.

6. The system of claim 1, wherein the system further comprises an OFDM redundancy based error correction module configured to use the redundancy in the OFDM scheme for error correction.

7. The system of claim 1, wherein the redundancy in the OFDM scheme is determined from IFFT matrix and FFT matrix.

8. The system of claim 1, wherein the trade-off between the redundancy in the OFDM scheme with the redundancy in (n,k) block code reduces “n”.

9. The system of claim 1, wherein the trade-off between the redundancy in the OFDM scheme with the redundancy in Cyclic Prefix enables size of the Cyclic Prefix to be any of reduced or increased or enabled or disabled.

10. A redundancy controller operatively coupled to a transmitter and to a receiver, said redundancy controller comprising:
a channel quality estimation module configured to determine quality of transmission channel between the transmitter and the receiver; and
an OFDM redundancy trade-off module configured to determine required redundancy in Orthogonal frequency-division multiplexing (OFDM) scheme based on the determined channel quality, and trade off the redundancy in the OFDM scheme with redundancy in any or a combination of (n,k) block code, power-based network resources, frequency-based network resources, time-based network resources, Peak-to-Average Power Ratio (PAPR) minimizer/reversal, Cyclic Prefix, removal of symbols from OFDM codeword and OFDM codeword decoder, in order to achieve the required transmission redundancy.

11. The controller of claim 10, wherein the controller further comprises an OFDM codeword size and duration control module configured to trade-off OFDM codeword size and duration based on the required OFDM redundancy for transmission of OFDM codeword.

12. The controller of claim 11, wherein the OFDM codeword size and duration control module is further configured to control number of OFDM symbols to be used for transmitting the OFDM codeword such that OFDM codeword decoder successfully decodes the OFDM codeword.

13. The controller of claim 11, wherein the OFDM codeword size and duration control module is further configured to remove OFDM symbols required for transmission of the OFDM codeword.

14. The controller of claim 11, wherein the OFDM codeword size and duration control module is further configured to reduce duration of the OFDM codeword.

15. The controller of claim 10, wherein the controller farther comprises an OFDM redundancy based error correction module configured to use the redundancy in the OFDM scheme for error correction.

16. The controller of claim 10, wherein the redundancy in the OFDM scheme is determined from IFFT matrix and FFT matrix.

17. The controller of claim 10, wherein the trade-off between the redundancy in the OFDM scheme with the redundancy in (n,k) block code reduces “n”.

18. A method for enabling OFDM coded transmission and reception, said method comprising the steps of:
determining, at a controller, quality of transmission channel between a transmitter and a receiver; and
determining, at the controller, required redundancy in Orthogonal frequency-division multiplexing (OFDM) scheme based on the determined channel quality; and
trading-off, at the controller, the redundancy in the OFDM scheme with redundancy in any or a combination of (n,k) block code, power-based network resources, frequency-based network resources, time-based network resources, Peak-to-Average Power Ratio (PAPR) minimizer/reversal, Cyclic Prefix, removal of symbols from OFDM codeword and OFDM codeword decoder, in order to achieve the required transmission redundancy.
